(19) United States
(12) Patent Application Publication
(10) Pub. No.: US 2005/0110159 A1
(43) Pub. Date: May 26, 2005

(54) Stacked integrated circuit device including multiple substrates and method of manufacturing the same

(76) Inventors: Chang-Woo Oh, Gyeonggi-do (KR); Dong-Gun Park, Gyeonggi-do (KR); Sung-Young Lee, Gyeonggi-do (KR); Jeong-Dong Choe, Gyeonggi-do (KR)

Correspondence Address: MARGER JOHNSON & MCCOLLOM, P.C., 1030 SW MORRISON STREET, PORTLAND, OR, 97205, US

(21) Appl. No.: 10/977,702

(22) Filed: Oct. 28, 2004

(30) Foreign Application Priority Data
Nov. 21, 2003 (KR) 2003-82974

(51) Int. Cl. H01L 29/04

(52) U.S. Cl. 257/777

(57) ABSTRACT

Provided are a stacked integrated circuit device including multiple substrates and a method of manufacturing the same. A first integrated circuit substrate, a first integrated circuit formed on the first integrated circuit substrate, and a first passivation insulating layer are sequentially formed. Then, wafer bonding technique for forming an SOI substrate is used, thereby forming a second integrated circuit substrate on the first passivation insulating layer. While forming a second integrated circuit on the second integrated circuit substrate, at least one device-connecting interconnect electrically connects the first and second Integrated circuits and penetrates the second integrated circuit substrate and the first passivation layer. A second passivation insulating layer is formed on an upper surface of the second integrated circuit.

### BACKGROUND OF THE INVENTION

This application claims the priority of Korean Patent Application No. 2003-82974, filed on Nov. 21, 2003, in the Korean Intellectual Property Office, the disclosure of which is incorporated herein in its entirety by reference.

1. Field of the Invention

The present invention relates to an integrated circuit device and a method of manufacturing the same, and more particularly to an integrated circuit device that including multiple substrates obtained by stacking a plurality of substrates, and a method of manufacturing the same.

2. Description of the Related Art

Decreased design rules minimize the dimensions of the elements of a device such as a transistor that forms an integrated circuit device. Such minimized dimensions of these elements make manufacturing difficult and complicated. Moreover, a Metal Oxide Silicon (MOS) transistor with a small design rule fabricated on a bulk silicon substrate degrades performance of the integrated circuit device due to a short channel effect, thus restricting the increase of the packing density on a bulk silicon substrate. The problems caused by the short channel effect can be partially solved when using a Silicon on Insulator (SOI) substrate is employed in place of the bulk silicon substrate. However, the SOI substrate brings about new problems such as heat dissipation.

On the other hand, the design of integrated circuit devices is gradually advancing to attain higher performance and lower power consumption, and it is necessary to furnish various functions in the integrated circuit devices. A System on Chip (SoC) device is representative of high-performance, multifunctional integrated circuit devices. The SoC device comprises several integrated circuits such as a memory circuit, a logic circuit, a digital circuit, and/or an analog circuit, in a single chip. Accordingly, dimensions of the integrated circuit device are increased, but manufacturing of an SoC that maximally uses inherent characteristics such as high performance, low power consumption, and high voltage of respective integrated circuits is limited. In some cases, integration itself may be impossible. Also, when a surface area of the integrated circuit device is increased, efficiency in using a wafer is decreased, which is economically inefficient.

One of method of manufacturing an integrated circuit device with high packing density, high performance and/or diverse performance is to use a stack package technique. Conventional stack package techniques are disclosed in, for example, U.S. Pat. Nos. 6,627,984; 6,627,480; and 6,621,169. According to these stack package techniques, integrated circuit chips respectively having the same or different kinds of integrated circuit devices are stacked, thereby manufacturing an integrated circuit device that has an increased packing density or performs diverse functions. The respective integrated circuit devices which form the stack packaged integrated circuit devices are electrically or functionally connected with one another by connecting respective bonding pads or connecting pads.

PCT/US2000/21031 discloses a method of bonding a double wafer. Here, precise alignment is used when arranging one wafer formed with a high temperature thermal sensor device and the other wafer formed with a low temperature CMOS device. After coating polyimide on bonding surfaces of the high temperature thermal sensor device and the low temperature CMOS device, pressure and heat are applied to attach the two wafers. Also, U.S. Pat. No. 6,080,640 (U.S. '640) issued to Gardner et al. discloses a highly packed integrated circuit device and a manufacturing method thereof in which two silicon substrates already formed with integrated circuits are bonded to each other. Here, metal interconnects are exposed in junction planes of respective silicon substrates, and two silicon substrates are bonded by connecting respective metal interconnects. However, in the above-cited PCT patent and U.S. '640, two integrated circuit devices already formed with the integrated circuits are attached facing each other. Consequently, more than three integrated circuit devices cannot be simultaneously bonded or stacked. Furthermore, bonding or stacking the integrated circuit devices makes the process complicated because two integrated circuit devices have to be accurately and precisely aligned with each other.

### SUMMARY OF THE INVENTION

The present invention provides a vertically stacked integrated circuit device including multiple substrates and a method of manufacturing the same, in which a packing density of the same or different integrated circuit devices can be increased without enlarging a surface area.

The present invention also provides a vertically stacked integrated circuit device including multiple substrates, which includes various kinds of integrated circuit devices such as an integrated circuit device fabricated on a bulk substrate, an integrated circuit device fabricated on an SOI substrate, a MMIC and/or a MEMS, and a method of manufacturing the same.

The present invention also provides a vertically stacked integrated circuit including multiple substrates and a method of manufacturing the same, which requires no additional process for forming interconnects for connecting respective vertically stacked integrated circuit devices.

To achieve the above, wafer bonding incorporated with manufacturing of an SOI integrated circuit substrate is applied. The wafer bonding used in manufacturing the SOI integrated circuit substrate is described in detail in Chapter 11, Volume 4, of “Silicon Processing for the VLSI Era,” entitled as:“Silicon-on-Insulator Technology,” written by S. Wolf. However, the present invention is an application of wafer bonding incorporated with the SOI substrate manufacturing technique, and the bonded substrates may include a silicon (Si) substrate, a silicon germanium (SiGe) substrate, a compound semiconductor substrate, or a substrate formed by stacking these substrates. Therefore, the substrate is of any kind and there is no limitation in the thickness of the substrate. Accordingly, the integrated circuit device of the present invention is distinguished from an integrated circuit device formed on a single SOI substrate. Rather, in the present invention, the same or different kinds of integrated circuit devices, e.g., MOSFETs, BJTs, HBTs, RTDs, MBSFETs, JFETs, HEMTs, Power Devices, are vertically stacked using the method of manufacturing the SOI integrated circuit substrate. The method of manufacturing the SOI integrated circuit substrate is used, thereby bonding an integrated circuit substrate on a passivation insulating layer of a completed integrated circuit device. Then, the same or different kind(s) of integrated circuits are formed on the integrated circuit substrate. Thereafter, the processes for manufacturing an SOI integrated circuit substrate and forming an integrated circuit are performed on the resultant integrated circuit substrate repeatedly, so that the integrated circuit device including multiple substrates obtained by vertically stacking the same or/and different kind(s) of integrated circuit devices can be manufactured.

According to an aspect of the present invention, there is provided a stacked integrated circuits device including multiple substrates. A first integrated circuit device includes a first integrated circuit substrate, a first integrated circuit formed on the first integrated circuit substrate, and a first passivation insulating layer formed on of the first integrated circuit. A second integrated circuit device includes second integrated circuit substrate formed on the first passivation insulating layer, a second integrated circuit formed on the second integrated substrate, and a second passivation insulating layer formed on the second integrated circuits. At least one device-connecting interconnect electrically connects the first integrated circuit to the second integrated circuit, and penetrates the second integrated circuits substrate and the first passivation insulating layer.

The second integrated circuit substrate may be a Silicon On Insulator (SOI) integrated circuit substrate. The second integrated circuit may have a Fully-Depleted Thin SOI MOSFETs. Also, the first integrated circuit substrate may be a bulk silicon substrate or an SOI integrated circuit substrate.

The integrated circuit device including multiple substrates may further include a third integrated circuit device including a third integrated circuit substrate formed on the second passivation insulating layer, a third integrated circuit formed on the third integrated substrate, and a third passivation insulating layer formed on the third integrated circuit. In this case, the device-connecting interconnect further includes an interconnect that electrically connects the second integrated circuit to the third integrated circuit, and penetrates the third integrated circuit substrate and the second passivation layer. Furthermore, the stacked integrated circuit device including multiple substrates may be a System on Chip (SoC) device. For example, each of the first integrated circuit substrate, the second integrated circuit substrate, and the third integrated circuit substrate may be one of a silicon substrate, a silicon germanium substrate, and a compound semiconductor substrate.

Each of the first integrated circuit device, the second integrated circuit device, and the third integrated circuit device of the SoC device includes at least one of a Metal Oxide Silicon Field Effect Transistor (MOSFET), a Bipolar Junction Transistor (BJT), a Hetero junction Bipolar Transistor (HBT), a Resistance Temperature Detector.(RTD), a Metal Schottky Field Effect Transistor (MESFET), a Junction Field Effect Transistor (JFET), a High Electrons Mobility Transistor (HEMT), and a Power device. Additionally, each of the first integrated circuit device, the second integrated circuit device, and the third integrated circuit device includes at least one of a resistor, a capacitor, and an inductor.

The first integrated circuit substrate may be a substrate obtained by stacking a bulk silicon substrate, a compound semiconductor substrate, and a silicon/silicon germanium or an insulating layer below the stacked substrate.

According to another aspect of the present invention, there is provided a method of manufacturing an integrated circuit device including multiple substrates. First, a first integrated circuit device including a first integrated circuit substrate, a first integrated circuit formed on the first integrated circuit substrate, and a first passivation insulating layer formed on an upper surface of the first integrated circuit is prepared. This can be performed by a conventional method of manufacturing an integrated circuit device using wafer bonding technique for fabricating an SOI substrate which may be a Smart-cut, Nanocleave Process or an Eltran. In more detail, a donor substrate including an interlayer for cutting formed to a predetermined depth is prepared and then bonded on the first passivation insulating layer, using suitable cleaning and annealing. By separating the donor substrate using the interlayer for cutting, the second integrated circuit substrate is formed on the first passivation insulating layer. Then, while forming a second integrated circuit on the second integrated circuit substrate, at least one device-connecting interconnect is formed, electrically connecting the first integrated circuit to the second integrated circuit and penetrating the second integrated circuit substrate and the first passivation layer. A second insulating layer is formed on an upper surface of the second integrated circuit, thereby forming a second integrated circuit device.

By repeating the manufacturing of the second integrated circuit device, the integrated circuit device including multiple substrates further includes a third integrated circuit device including a third integrated circuit substrate formed on the second passivation insulating layer, a third integrated circuit formed on the third integrated circuit substrate, and a third passivation insulating layer formed on an upper surface of the third integrated circuit. The device-connecting interconnect further includes an interconnect that penetrates the third integrated circuit substrate and the second passivation layer, and electrically connects the second integrated circuit to the third integrated circuit. As described above, the first integrated circuit substrate, the second integrated circuit substrate, and the third integrated circuit substrate are respectively formed of the same or different material(s) such as silicon, silicon germanium and a compound semiconductor. The first, second, and third integrated circuit substrates have no limitation in thickness and in number being stacked.

### BRIEF DESCRIPTION OF THE DRAWINGS

The above and other features and advantages of the present invention will become more apparent by describing in detail exemplary embodiments thereof with reference to the attached drawings in which:

FIGS. 1 through 5 are schematic sectional views for illustrating a method of manufacturing an integrated circuit device including multiple substrates according to an embodiment of the present invention; and

FIG. 6 is a schematic sectional view of a structure of an electronic appliance having display means including an integrated circuit device, and further including a plurality of substrates, according to another embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art. Like reference numerals in the drawings denote like elements, and thus their description will be omitted.

While the present invention is described using an exemplary integrated circuit device with a typical silicon bulk MOSFET and an integrated circuit with an SOI MOSFET, it may also be applied as well to different kinds of integrated circuit devices.

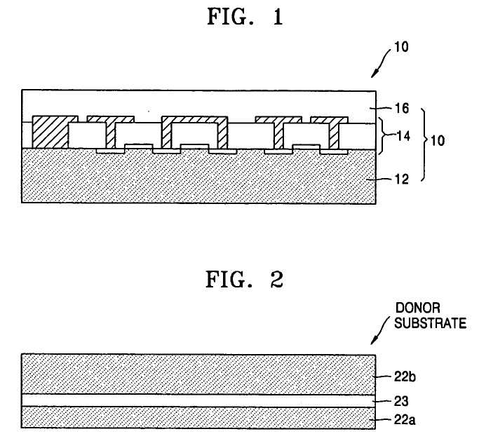

Referring to FIG. 1, a first integrated circuit device 10 is prepared. The first integrated circuit device 10 includes a first integrated circuit substrate 12, a first integrated circuit 14 and a first passivation insulating layer 16. The first integrated circuit substrate 12 can be a bulk silicon substrate, an SOI substrate or a substrate of another material. In the present embodiment, the first integrated circuit substrate 12 is a bulk silicon substrate. The first integrated circuit 14 can include elements such as active devices, such as a MOSFET, passive devices, such as a resistor, a capacitor and an inductor, and various interconnect lines, such as a word line and bit line, which are formed in or on the first integrated circuit substrate 12. The pattern of the first integrated circuit 14 as shown in FIG. 1 is only illustrative, and is not limited to the present embodiment, and the first integrated circuit 14 may include stacked devices and multi-layered interconnects. The first passivation insulating layer 16 protects the first integrated circuit 14, may be formed of a silicon oxide.

Next a second integrated circuit substrate 22a is formed on the first passivation insulating layer 16. When forming the second integrated circuit substrate 22a on the first passivation insulating layer 16, a method of manufacturing an SOI substrate, such as wafer bonding, is utilized. Wafer bonding can include a smart-cut method, a nanocleave method or an eltran method. The smart-cut method can include hydrogen-implantation-induced layer splitting, in which the induced layer becomes an inter layer for cutting. Nanocleave is carried out such that a SiGe/Si epitaxial layer is grown, wafer bonding is performed at a low temperature, and cutting is performed at room temperature. A single-crystal silicon integrated circuit substrate with a thickness of 100 nm or less can thereby be formed. The eltran method is characterized by growing an epitaxial layer on a porous silicon layer, thus performing bonding and etch-back on the SOI. Then, the epitaxial layer is grown as above and is transferred by wafer bonding. FIGS. 2, 3 and 4 illustrate a method of forming the second integrated circuit substrate 22a, using a wafer bonding technique.

Referring to FIG. 2, a silicon substrate is prepared using donor substrates 22a, 22b and 23, which will supply a second integrated circuit substrate 22a bonded on the first passivation insulating layer 16 later. An interlayer 23 for cutting is formed between the donor substrates 22a and 22b. Methods of forming the interlayer 23 for cutting as well as of manufacturing the donor substrates 22a and 22b are different according to the above-mentioned wafer bonding methods.

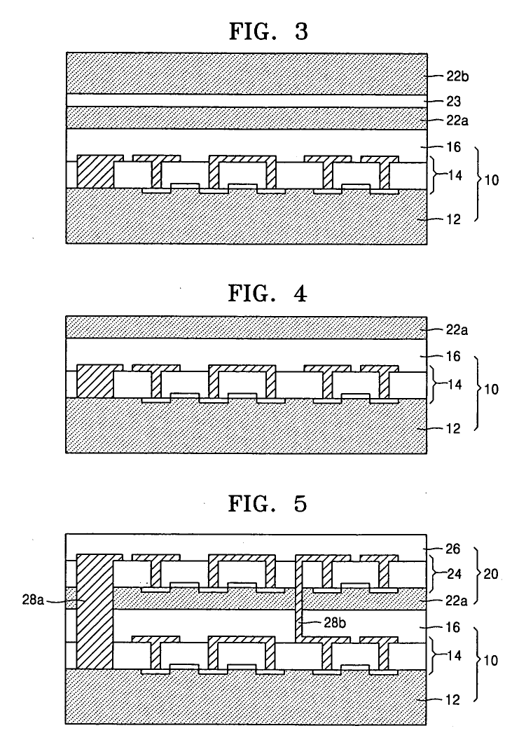

Referring to FIG. 3, the donor substrates 22a, 22b, and 23 are attached to the first passivation layer 16 of the first integrated circuit device 10. Therefore, the first integrated circuit device can be formed according to the above-mentioned wafer bonding technique. Because no circuit is formed on the donor substrates 22a, 22b and 23, precise alignment is not required during the bonding process. Then, cleaning and annealing required for bonding the donor substrates 22a, 22b and 23 are carried out. In the present embodiment, since a predetermined integrated circuit is formed in the first integrated circuit device 10, it is not preferable to perform annealing at a substantially high temperature.

Referring to FIG. 4, the second integrated circuit substrate 22a is transferred by separating the donor substrates 22a, 22b and 23. The donor substrates 22a, 22b and 23 are separated at the interlayer 23 for cutting. As a result, the remaining donor substrate 22b is removed, and an outer surface of the second integrated circuit substrate 22a is exposed. By performing Chemical Mechanical Polishing (CMP), cleaning and/or annealing on the exposed outer surface of the second integrated circuit substrate 22a, a desired second integrated circuit substrate 22a having a single-crystal structure is formed.

Then, referring to FIG. 5, a second integrated circuit 24 is formed on the second integrated circuit substrate 22a. The second integrated circuit 24 may be identical to or different from the first integrated circuit 14. In other words, the first integrated circuit device 10 including the first integrated circuit 14 may be identical to or different from a second integrated circuit device 20 including the second integrated circuit 24.

Furthermore, while forming the second integrated circuit 24, at least one device-connecting interconnect 28a is simultaneously formed, so that the first integrated circuit 14 is electrically connected to the second integrated circuit 24. The device-connecting interconnect 28a penetrates through at least the second integrated circuit substrate 22a and the first passivation insulating layer 16 according to the required electrical connections between the devices. The device-connecting interconnect 28a may be used by transmitting a simple signal and/or may be used by applying a bias of a predetermined potential commonly to the first and second integrated circuit devices 10 and 20. When the second integrated circuit 24 and the device-connecting interconnect 28a are completely formed, a second passivation insulating layer 26 is then formed thereon. However, the device-connecting interconnect 28a may penetrate the second passivation insulating layer 26. In this case, the device-connecting interconnect 28a may be formed after forming the second passivation insulating layer 26.

Thus, the integrated circuit device including a plurality of vertically stacked integrated circuit substrates 12 and 22a is formed. The integrated circuit device including a plurality of substrates according to the present embodiment may have the structure formed by stacking a pair of integrated circuit devices as shown in FIG. 5, or a structure formed by stacking more than two integrated circuit devices. In other words, the method illustrated by FIGS. 2 through 5 can be repeated, thereby manufacturing an integrated circuit device having three or four vertically stacked integrated circuit devices.

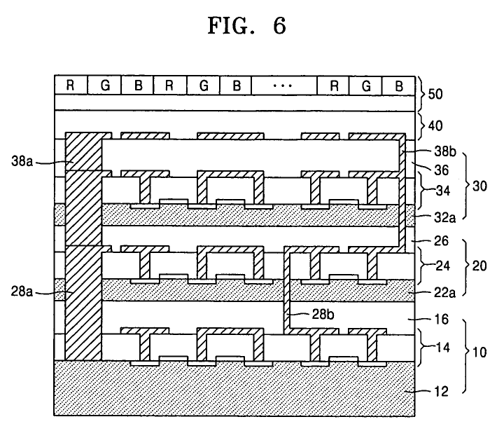

FIG. 6 is a sectional view of structure of an electronic appliance for display means having integrated circuit devices 10, 20 and 30 including a plurality of substrates according to another embodiment of the present invention. FIG. 6 is an example of the integrated circuit device including a plurality of substrates according to the present invention. Referring to FIG. 6, the integrated circuit devices 10, 20 and 30 form a vertically stacked SoC including three integrated circuit devices. An interconnect unit 40 and a display unit 50 including an image sensor are disposed on the SoC, thereby forming an electronic display appliance. That is, the integrated circuit devices 10, 20 and 30 including a plurality of substrates are formed by vertically stacking a plurality of integrated circuits required for the electronic display appliance. More specifically, the first integrated circuit device 10 may include a CPU, a microprocessor, or an integrated circuit memory device. The second integrated circuit device 20 may include a CPU, a microprocessor, an integrated circuit memory device, or a Digital Signal Processor (DSP). The 3rd integrated circuit device 30 may include a driver integrated circuit, a digital signal processor, or a high frequency integrated circuit device. Moreover, the display unit 50 may be an Organic Electro Luminescence Display (OELD), a Plasma Display Panel (PDP), or a Field Emission Display (FED).

Embodiments of the present invention utilize CMP or SOI wafer fabricating to manufacture the highly integrated circuit device having multi-layered structure in which the same and/or different kind(s) of integrated circuit devices are stacked. In particular, the integrated circuit device is much thinner than a stack-packaged integrated circuit device, and the integrated circuit device functioning as a system, such as an SoC, as well as carrying out a single function can be manufactured.

According to embodiments of the present invention, an integrated circuit device having multiple substrates including both a bulk integrated circuit device and an SOI integrated circuit device can be manufactured, thereby maximally utilizing advantages of the respective integrated circuit devices. Moreover, the SOI integrated circuit device can be applied as a floating body or a body-tied structure, thereby enabling diverse application.

Since the device-connecting interconnect is formed while manufacturing the integrated circuit, the integrated circuit device can have a small structure. Also, there is no need to separately perform an interconnect forming process that connects respective devices after packaging, so that the manufacturing process is also simplified.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A stacked integrated circuit device including a plurality of substrates, comprising:
a first integrated circuit device including a first integrated circuit substrate, a first integrated circuit formed on the first integrated circuit substrate, and a first passivation insulating layer formed on the first integrated circuit;
a second integrated circuit device including a second integrated circuit substrate formed on the first passivation insulating layer, a second integrated circuit formed on the second integrated substrate, and a second passivation insulating layer formed on the second integrated circuit; and
at least one device-connecting interconnect electrically connecting the first integrated circuit to the second integrated circuit, and penetrating the second integrated circuit substrate and the first passivation insulating layer.

2. The stacked integrated circuit device of claim 1, wherein the second integrated circuit substrate comprises a Silicon On Insulator (SOI) integrated circuit substrate.

3. The stacked integrated circuit device of claim 1, wherein the second integrated circuit is a Fully-Depleted Thin SOI MOSFET.

4. The stacked integrated circuit device of claim 1, wherein the first integrated circuit substrate comprises a substrate obtained by stacking a bulk silicon substrate, a compound semiconductor substrate, a silicon/silicon germanium layer and/or an insulating layer.

5. The stacked integrated circuit device of claim 1, further comprising:
a third integrated circuit device including a third integrated circuit substrate formed on the second passivation insulating layer, a third integrated circuit formed on the third integrated substrate, and a third passivation insulating layer formed on the third integrated circuit,
wherein the device-connecting interconnect further comprises an interconnect electrically connecting the second integrated circuit to the third integrated circuit, and penetrating the third integrated circuit substrate and the second passivation layer.

6. The stacked integrated circuit device of claim 5, wherein the stacked integrated circuit device is a System on Chip (SoC) device.

7. The vertically stacked integrated circuit device of claim 6, wherein each of the first integrated circuit substrate, the second integrated circuit substrate, and the third integrated circuit substrate comprises one of a silicon substrate, a silicon germanium substrate, and a compound semiconductor substrate.

8. The stacked integrated circuit device of claim 6, wherein each of the first integrated circuit device, the second integrated circuit device, and the third integrated circuit device comprises at least one of a Metal Oxide Silicon Field Effect Transistor (MOSFET), a Bipolar Junction Transistor (BJT), a Hetero junction Bipolar Transistor (HBT), a Resistance Temperature Detector (RTD), a Metal Schottky Field Effect Transistor (MESFET), a Junction Field Effect Transistor (JFET), a High Electrons Mobility Transistor (HEMT), and a Power device.

9. The stacked integrated circuit device of claim 8, wherein each of the first integrated circuit device, the second integrated circuit device, and the third integrated circuit device comprises at least one of a resistor, a capacitor, and/or an inductor.

10. The stacked integrated circuit device of claim 6, wherein each of the first integrated circuit device, the second integrated circuit device, and the third integrated circuit device comprises at least one of a silicon integrated circuit, a MMIC, a MEMS, a Driver integrated circuit, an integrated circuit for DSP, an RF integrated circuit and/or a BiCMOS.

11. A method of manufacturing an integrated circuit device including a plurality of substrates comprising:
(a) forming a first integrated circuit device including a first integrated circuit substrate, a first integrated circuit formed on the first integrated circuit substrate, and a first passivation insulating layer formed on the first integrated circuit;
(b) forming a second integrated circuit substrate on the first passivation insulating layer using wafer bonding technique for fabricating an SOI substrate;
(c) forming a second integrated circuit on the second integrated circuit substrate by forming at least one device-connecting interconnect electrically connecting the first integrated circuit to the second integrated circuit, the device-connecting interconnect penetrating the second integrated circuit substrate and the first passivation layer; and
(d) forming a second passivation insulating layer on the second integrated circuit.

12. The method of manufacturing an integrated circuit device of claim 11, wherein the forming the second integrated circuit substrate comprises:
preparing a donor substrate including an interlayer for cutting having a predetermined thickness;
bonding the donor substrate to the first passivation insulating layer;
separating the donor substrate into discrete portions using the interlayer for cutting, thereby leaving after separation the second integrated circuit substrate located on the first passivation insulating layer.

13. The method of manufacturing an integrated circuit device of claim 11, wherein the forming of the second integrated circuit substrate includes a Smart-Cut, a Nanocleave, or an Eltran process.

14. The method of manufacturing an integrated circuit device of claim 11, further comprising forming a third integrated circuit device that has a third integrated circuit substrate formed on the second passivation insulating layer, the third integrated circuit device further including a third integrated circuit formed on the third integrated circuit substrate, and a third passivation insulating layer formed on the third integrated circuit,
wherein the device-connecting interconnect further includes an interconnect penetrating the third integrated circuit substrate and the second passivation layer, and electrically connecting the second integrated circuit to the third integrated circuit.

15. The method of manufacturing an integrated circuit device of claim 14, wherein at least one of the first, second and third integrated circuit devices comprises a System on Chip (SoC) device.

16. The method of manufacturing an integrated circuit device of claim 15, wherein each of the first integrated circuit substrate, the second integrated circuit substrate, and the third integrated circuit substrate comprises one of a silicon substrate, a silicon germanium substrate, a compound semiconductor substrate, and a composite substrate combining the substrates.

17. The method of manufacturing an integrated circuit device of claim 15, wherein each of the first integrated circuit device, the second integrated circuit device, and the third integrated circuit device comprises at least one of a Metal Oxide Silicon Field Effect Transistor (MOSFET), a Bipolar Junction Transistor (BJT), a Hetero junction Bipolar Transistor (HBT), a Resistance Temperature Detector (RTD), a Metal Schottky Field Effect Transistor (MESFET), a Junction Field Effect Transistor (JFET), a High Electrons Mobility Transistor (HEMT), and/or a Power device.

18. The method of manufacturing an integrated circuit device of claim 17, wherein the first integrated circuit device, the second integrated circuit device, and the third integrated circuit device comprises at least one of a resistor, a capacitor, and/or an inductor.

19. The method of manufacturing an integrated circuit device of claim 15, wherein each of the first integrated circuit device, the second integrated circuit device, and the third integrated circuit device comprises at least one of a silicon integrated circuit, a MMIC, a MEMS, a Driver integrated circuit, an integrated circuit for DSP, an RF integrated circuit and/or a BiCMOS.
